(19) United States
(12) Patent Application Publication
(10) Pub. No.: US 2021/0325513 A1
(43) Pub. Date: Oct. 21, 2021

(54) LIGHT SOURCE APPARATUS, DETECTION METHOD, AND SENSING MODULE

(71) Applicant: SONY SEMICONDUCTOR SOLUTIONS CORPORATION, KANAGAWA (JP)

(72) Inventors: MITSUSHI TABATA, TOKYO (JP); TAKASHI MASUDA, KANAGAWA (JP)

(21) Appl. No.: 17/250,684

(22) PCT Filed: Jul. 12, 2019
(86) PCT No.: PCT/JP2019/027701

§ 371 Date: Feb. 19, 2021

(30) Foreign Application Priority Data
Aug. 31, 2018 (JP) 2018-163941

(51) Int. Cl. G01S 7/484; G01S 7/481; H01S 5/00; H01S 5/042; H01S 5/42; G01S 17/10; G01S 17/89

(52) U.S. Cl. CPC G01S 7/484; G01S 7/4815; H01S 5/0028; G01S 17/89; H01S 5/423; G01S 17/10; H01S 5/042

(57) ABSTRACT

Attaining a more compact apparatus while also enabling the voltage to be detected for each light-emitting element in a light source apparatus provided with an emission section in which a plurality of vertical-cavity surface-emitting laser light-emitting elements is arrayed. A light source apparatus according to the present technology includes an emission section in which a plurality of vertical-cavity surface-emitting laser light-emitting elements is arrayed, and a detection section configured to detect a voltage at an anode or a cathode of the plurality of light-emitting elements in the emission section individually by time division. With this arrangement, it is not necessary to provide a circuit for detecting voltage with respect to each light-emitting element, and it becomes possible to attain a more compact apparatus.

### TECHNICAL FIELD

The present technology relates to a light source apparatus provided with an emission section in which a plurality of vertical-cavity surface-emitting laser light-emitting elements is arrayed, a detection method that detects the voltage of the light-emitting elements, and a sensing module provided with an image sensor that captures an image by receiving light that is emitted by the emission section and then reflected by a subject.

### BACKGROUND ART

The vertical-cavity surface-emitting laser (VCSEL) is known as a light-emitting element that emits laser light (see Patent Literatures 1 and 2 below, for example).

A VCSEL light-emitting element is configured such that an oscillator is formed perpendicular to the semiconductor substrate surface and laser light is emitted in the perpendicular direction, and in recent years, VCSELs have been used widely as light sources when measuring the distance to a subject according to a structured light (STL) method and a time of flight (ToF) method, for example.

### CITATION LIST

### Patent Document

Patent Document 1: Japanese Patent Application Laid-Open No. 2012-195436
Patent Document 2: Japanese Patent Application Laid-Open No. 2015-103727

### SUMMARY OF THE INVENTION

### Problems to be Solved by the Invention

Here, in the case of measuring the distance to a subject according to an STL method or a ToF method, a light source apparatus in which a plurality of VCSEL light-emitting elements is disposed in a two-dimensional array is used. Specifically, the subject is illuminated with light emitted from the plurality of light-emitting elements, and the distance to the subject is measured on the basis of an image obtained by receiving reflected light from the subject.

Here, to cause the light-emitting elements to emit light appropriately, it is effective to detect the voltage produced in the light-emitting elements to control the power supply voltage or stop the circuit. Also, to increase safety, it is effective to detect voltage abnormalities in the light-emitting elements to control the power supply voltage.

However, providing a circuit for detecting voltage with respect to each light-emitting element leads to a larger circuit scale and makes it difficult to miniaturize the light source apparatus, and is therefore undesirable.

The present technology has been devised in light of the above circumstances, and an object is to attain a more compact apparatus while also enabling the voltage to be detected for each light-emitting element in a light source apparatus provided with an emission section in which a plurality of vertical-cavity surface-emitting laser light-emitting elements is arrayed.

### Solutions to Problems

A light source apparatus according to the present technology includes an emission section in which a plurality of vertical-cavity surface-emitting laser light-emitting elements is arrayed, and a detection section configured to detect a voltage at an anode or a cathode of the plurality of light-emitting elements in the emission section described above individually by time division.

With this arrangement, it is not necessary to provide a circuit for detecting voltage with respect to each light-emitting element.

In the light source apparatus according to the present technology described above, it is desirable that the detection section switch the light-emitting element to detect according to a clock, and include a counter configured to count in synchronization with the clock.

From the count value of the counter, it is possible to specify the light-emitting element from which the detected voltage value has been detected.

In the light source apparatus according to the present technology described above, it is desirable that the detection section include a detection line of the voltage from each light-emitting element, and a voltage follower inserted onto each detection line and having a controllable ON/OFF state.

With this arrangement, not only a detection line time-division selection function but also a detection line voltage drop prevention function can be provided together.

It is desirable that the light source apparatus according to the present technology described above further include a driving circuit configured to send a driving current to the plurality of light-emitting elements through a current mirror circuit.

With this arrangement, it is not necessary to use a power supply circuit with a constant current control function to send a constant current to the light-emitting elements.

In the light source apparatus according to the present technology described above, it is desirable that the current mirror circuit be connected to an anode side of the light-emitting elements, and that the detection section be configured to detect the voltage at the anode of the light-emitting elements.

With this arrangement, it is possible to detect voltage appropriately with consideration for specific individual differences among each of the light-emitting elements and the driving elements in the current mirror circuit.

In the light source apparatus according to the present technology described above, it is desirable that the current mirror circuit be connected to a cathode side of the light-emitting elements, and that the detection section be configured to detect the voltage at the cathode of the light-emitting elements.

With this arrangement, it is possible to detect voltage appropriately with consideration for specific individual differences among each of the light-emitting elements and the driving elements in the current mirror circuit.

It is desirable that the light source apparatus according to the present technology described above further include a determination section configured to determine a presence of an abnormality in the light-emitting elements on the basis of the voltage individually detected by the detection section.

With this arrangement, it is not necessary to provide a circuit for detecting a voltage abnormality with respect to each light-emitting element.

In the light source apparatus according to the present technology described above, it is desirable that the determination section be configured to determine whether or not a value of the voltage is inside a predetermined range as the determination of the presence or absence of an abnormality in the light-emitting elements.

With this arrangement, the presence or absence of a voltage abnormality in a light-emitting element caused by a discontinuity, a short, a ground fault, or the like can be specified appropriately.

It is desirable that the light source apparatus according to the present technology described above further includes a power supply circuit configured to generate a power supply voltage used in common to the drive the plurality of light-emitting elements, and a control section configured to control the power supply circuit on the basis of the voltage detected by the detection section.

With this arrangement, in a configuration in which a plurality of light-emitting elements is driven on the basis of a common power supply voltage generated by a common power supply circuit, it is possible to control the power supply such that, for example, if a voltage abnormality in a light-emitting element is recognized, the operation of the power supply circuit may be stopped or the like to increase safety, or the magnitude of the power supply voltage may be adjusted to suit a light-emitting element having a high detected voltage and thereby cause all light-emitting elements targeted for emission to emit light appropriately.

In the light source apparatus according to the present technology described above, it is desirable that the control section be configured to control the power supply circuit to raise the power supply voltage in response to the detection section detecting the voltage at a predetermined threshold or higher.

With this arrangement, in a configuration in which a plurality of light-emitting elements is driven on the basis of a common power supply voltage generated by a common power supply circuit, it is possible to adjust the magnitude of the common power supply voltage to suit a light-emitting element having a high detected voltage.

It is desirable that the light source apparatus according to the present technology described above further include a driving circuit having a switch provided for each light-emitting element and configured to drive the light-emitting elements in the emission section individually.

With this arrangement, the emission section can be made to emit light according to any emission pattern (two-dimensional light/dark pattern).

Further, a detection method according to the present technology includes individually detecting, by time division, a voltage at an anode or a cathode of a plurality of light-emitting elements in an emission section in which a plurality of vertical-cavity surface-emitting laser light-emitting elements is arrayed.

Furthermore, a sensing module according to the present technology includes the light source apparatus according to the present technology described above, and an image sensor that captures an image by receiving light that is emitted by the emission section provided in the light source apparatus and then reflected by a subject.

Action similar to the light source apparatus according to the present technology described above are also obtained by such a detection method and sensing module.

### Effects of the Invention

According to the present technology, it is possible to attain a more compact apparatus while also enabling the voltage to be detected for each light-emitting element in a light source apparatus provided with an emission section in which a plurality of vertical-cavity surface-emitting laser light-emitting elements is arrayed.

Note that, the effect described here is not necessarily limited, and can be any effect described in the present disclosure.

### BRIEF DESCRIPTION OF DRAWINGS

FIG. 1 is a diagram illustrating an exemplary configuration of a distance measuring apparatus as an embodiment of a light source apparatus according to the present technology.

FIG. 2 is a diagram explaining a technique of measuring distance according to a structured light (STL) method.

FIG. 3 is a diagram illustrating an exemplary circuit configuration of the light source apparatus as an embodiment.

FIG. 4 is a diagram illustrating a modification of a driving circuit provided in the light source apparatus as an embodiment.

FIG. 5 is a diagram illustrating a circuit configuration as a modification of the light source apparatus as an embodiment.

FIG. 6 is a diagram illustrating an exemplary substrate configuration of the light source apparatus as an embodiment.

FIG. 7 is a diagram illustrating another exemplary substrate configuration of the light source apparatus as an embodiment.

FIG. 8 is a diagram illustrating yet another exemplary substrate configuration of the light source apparatus as an embodiment.

FIG. 9 is a diagram illustrating an exemplary arrangement of temperature sensors provided in the light source apparatus as an embodiment.

FIG. 10 is a diagram illustrating an exemplary structure of an emission section provided in the light source apparatus as an embodiment.

FIG. 11 is a diagram illustrating another exemplary structure of an emission section provided in the light source apparatus as an embodiment.

FIG. 12 is an explanatory diagram of an exemplary configuration for achieving voltage detection as an embodiment.

FIG. 13 is a diagram illustrating an example of the relationship between a clock used in time-division detection, a voltage value (HDR) detected by time division, and an abnormality detection signal.

FIG. 14 is a flowchart illustrating a specific processing procedure to be executed to achieve abnormality determination and power supply control as an embodiment.

FIG. 15 is a diagram illustrating an example of the layout, on a chip, of each component of a driving section that drives an emission section.

FIG. 16 is an explanatory diagram of a modification that omits a counter.

FIG. 17 is an explanatory diagram of a modification that uses a voltage follower with an enable function.

### MODE FOR CARRYING OUT THE INVENTION

Hereinafter, the attached drawings will be referenced to describe embodiments according to the present technology in the following order.

<1. Configuration of distance measuring apparatus>

<2. Distance measuring techniques>

<3. Circuit configuration related to emission driving>

<4. Variations in substrate configuration>

<5. Exemplary VCSEL structure>

<6. Voltage detection and control as an embodiment>

<7. Summary of embodiment and modifications>

<8. Present technology>

<1. Configuration of Distance Measuring Apparatus>

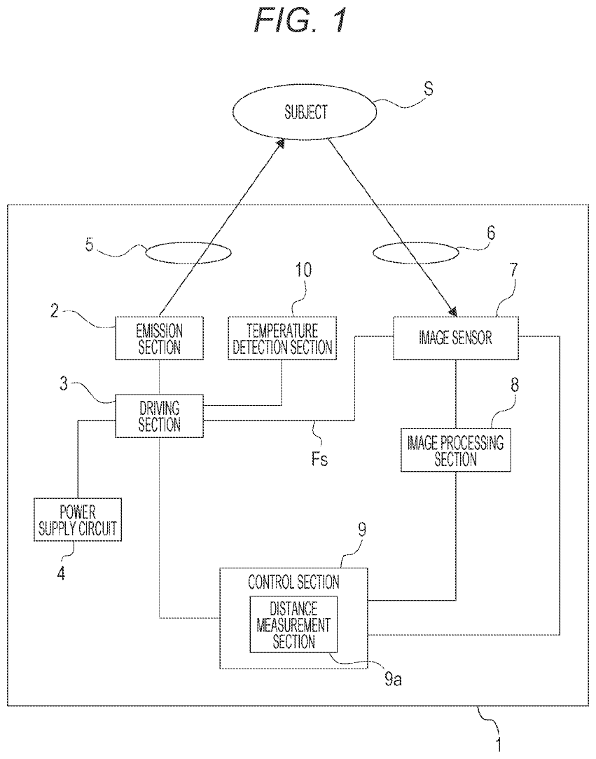

FIG. 1 illustrates an exemplary configuration of a distance measuring apparatus 1 as an embodiment of a light source apparatus according to the present technology.

As illustrated in the diagram, the distance measuring apparatus 1 is provided with an emission section 2, a driving section 3, a power supply circuit 4, an emission-side optical system 5, an imaging-side optical system 6, an image sensor 7, an image processing section 8, a control section 9, and a temperature detection section 10.

The emission section 2 emits light from a plurality of light sources. As described later, the emission section 2 in this example includes vertical-cavity surface-emitting laser (VCSEL) light-emitting elements 2a as the light sources, and these light-emitting elements 2a are arrayed in a predetermined pattern, such as a matrix for example.

The driving section 3 includes an electrical circuit for driving the emission section 2.

The power supply circuit 4 generates a power supply voltage for the driving section 3 (an output voltage Vo described later) on the basis of an input voltage (an input voltage Vin described later) from a source such as a battery not illustrated that is provided in the distance measuring apparatus 1, for example. The driving section 3 drives the emission section 2 on the basis of the power supply voltage.

Light emitted by the emission section 2 illuminates, through the emission-side optical system 5, a subject S treated as the target of distance measurement. Thereafter, reflected light from the subject S out of the light emitted in this way is incident on the imaging surface of the image sensor 7 through the imaging-side optical system 6.

The image sensor 7 is an image sensor such as a charge-coupled device (CCD) sensor or a complementary metal-oxide semiconductor (CMOS) sensor for example that receives reflected light from the subject S incident through the imaging-side optical system 6 as above, and converts the received light to output an electrical signal.

The image sensor 7 executes processes such as a correlated double sampling (CDS) process and an automatic gain control (AGC) process on the electrical signal obtained by photoelectric conversion of the received light, and furthermore performs an analog/digital (A/D) conversion process. An image signal is then output as digital data to the image processing section 8 downstream.

Additionally, the image sensor 7 in this example outputs a frame synchronization signal Fs to the driving section 3. With this arrangement, the driving section 3 is capable of causing the light-emitting elements 2a in the emission section 2 to emit light at timings according to the frame cycle of the image sensor 7.

The image processing section 8 is configured as an image processor such as a digital signal processor (DSP), for example. The image processing section 8 performs various types of image signal processing on the digital signal (image signal) input from the image sensor 7.

The control section 9 is provided with an information processing device such as a microcomputer including components such as a central processing unit (CPU), read-only memory (ROM), and random access memory (RAM), or a DSP. The control section 9 controls the driving section 3 for controlling the emission operations by the emission section 2 and controls imaging operations by the image sensor 7.

The control section 9 includes functions that act as a distance measurement section 9a. The distance measurement section 9a measures the distance to the subject S on the basis of the image signal input through the image processing section 8 (that is, the image signal obtained by receiving reflected light from the subject S). The distance measurement section 9a in this example measures the distance to different portions of the subject S, thereby making it possible to identify the three-dimensional shape of the subject S.

Herein, specific techniques of measuring distance in the distance measuring apparatus 1 will be described in further detail later.

The temperature detection section 10 detects the temperature of the emission section 2. A configuration that detects temperature using a diode for example can be adopted as the temperature detection section 10.

In this example, information about the temperature detected by the temperature detection section 10 is supplied to the driving section 3, thereby enabling the driving section 3 to drive the emission section 2 on the basis of the information about the temperature.

<2. Distance Measuring Techniques>

As the technique of measuring distance in the distance measuring apparatus 1, a technique of measuring distance according to a structured light (STL) method or a time of flight (ToF) method can be adopted, for example.

The STL method measures distance on the basis of an image obtained by imaging the subject S illuminated with light having a predetermined light/dark pattern, such as a dot pattern or a grid pattern, for example.

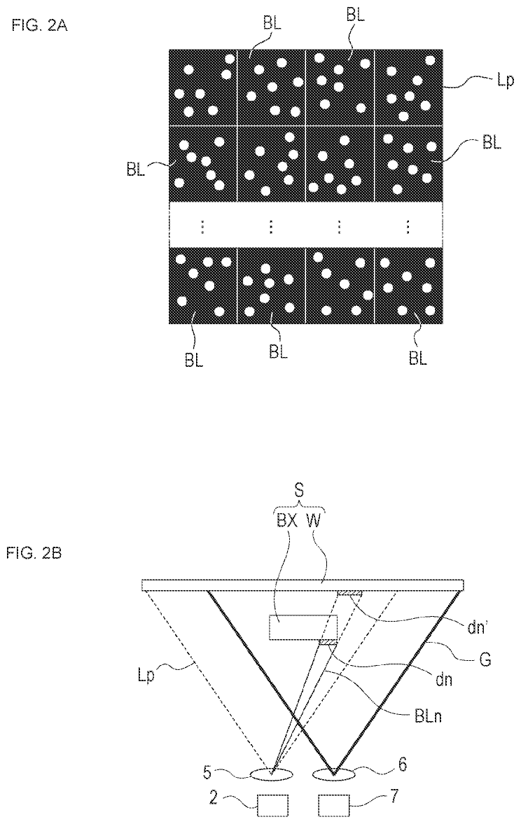

FIG. 2 is a diagram explaining the STL method.

In the STL method, the subject S is illuminated with pattern light Lp having a dot pattern like the one illustrated in FIG. 2A, for example. The pattern light Lp is divided into a plurality of blocks BL, and a different dot pattern is assigned to each block BL (the dot patterns are not duplicated among the blocks BL).

FIG. 2B is a diagram explaining the principle of distance measurement according to the STL method.

In the example herein, a wall W and a box BX placed in front are treated as the subject S, and the subject S is illuminated with pattern light Lp. In the diagram, “G” schematically represents the angle of view of the image sensor 7.

Also, “BLn” in the diagram means the light from a certain block BL among the pattern light Lp, and “dn” means the dot pattern of the block BLn appearing in the captured image obtained by the image sensor 7.

Here, in the case where the box BX in front of the wall W does not exist, the dot pattern of the block BLn appears in the captured image at a position “dn′” in the diagram. In other words, the position where the pattern of the block BLn appears in the captured image is different between the case where the box BX exists and the case where the box BX does not exist, and more specifically, a distortion in the pattern occurs.

The STL method is a method of obtaining the shape and the depth of the subject S by utilizing how the illuminating pattern is distorted by the physical shape of the subject S in this way. Specifically, the STL method is a method of obtaining the shape and the depth of the subject S from the way in which the pattern is distorted.

In the case of adopting the STL method, an infrared (IR) image sensor with a global shutter is used as the image sensor 7, for example. Additionally, in the case of the STL method, the distance measurement section 9a controls the driving section 3 such that the emission section 2 emits pattern light, and in addition, detects pattern distortion in the image signal obtained through the image processing section 8, and calculates the distance on the basis of the way in which the pattern is distorted.

Next, the ToF method measures the distance to a target by detecting the time of flight (time difference) of light that is emitted by the emission section 2, reflected by the target, and arrives at the image sensor 7.

In the case of adopting what is called the direct ToF method as the ToF method, a single-photon avalanche diode (SPAD) is used as the image sensor 7, and the emission section 2 is pulse-driven. In this case, the distance measurement section 9a calculates the time difference from emission to reception for light that is emitted by the emission section 2 and received by the image sensor 7 on the basis of the image signal input through the image processing section 8, and calculates the distance to different portions of the subject S on the basis of the time difference and the speed of light.

Note that in the case of adopting what is called the indirect ToF method (phase difference method) as the ToF method, an IR image sensor is used as the image sensor 7, for example.

<3. Circuit Configuration Related to Emission Driving>

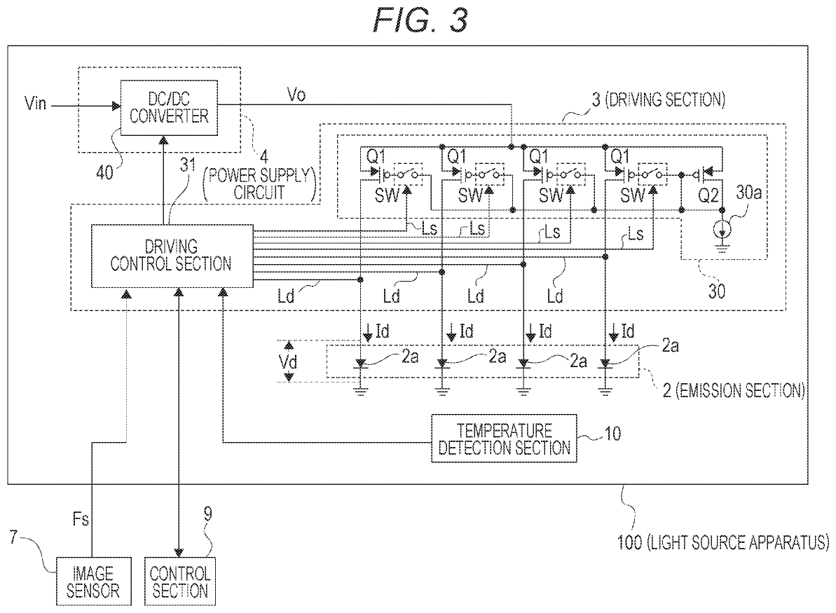

FIG. 3 illustrates an exemplary circuit configuration of a light source apparatus 100 that includes the emission section 2, the driving section 3, and the power supply circuit 4 illustrated in FIG. 1. Note that in addition to the exemplary circuit configuration of the light source apparatus 100, FIG. 3 also illustrates the image sensor 7 and the control section 9 illustrated in FIG. 1.

In this example, the emission section 2, the driving section 3, and the power supply circuit 4 are formed on a common substrate (a substrate B described later). Here, the configuration unit that includes at least the emission section 2 and is formed on a common substrate with the emission section 2 is referred to as the light source apparatus 100.

As illustrated in the diagram, the light source apparatus 100 is provided with the temperature detection section 10 in addition to the emission section 2, the driving section 3, and the power supply circuit 4.

The emission section 2 is provided with a plurality of VCSEL light-emitting elements 2a as described earlier. In FIG. 3, the number of light-emitting elements 2a is treated as “4” for convenience, but the number of light-emitting elements 2a in the emission section 2 is not limited thereto, and is sufficiently at least two or more.

The power supply circuit 4 is provided with a DC/DC converter 40, and generates a direct-current (DC) output voltage Vo on the basis of an input voltage Vin supplied as a DC voltage. The output voltage Vo is used as a power supply voltage by which the driving section 3 drives the emission section 2.

In this example, the DC/DC converter 40 is configured to be capable of adjusting the magnitude (current value) of the output voltage Vo.

The driving section 3 is provided with a driving circuit 30 and a driving control section 31.

The driving circuit 30 includes a driving element Q1 and a switch SW for each light-emitting element 2a, as well as a current control element Q2 and a constant current source 30a.

A field-effect transistor (FET) is used for the driving element Q1 and the current control element Q2, and in this example, a P-channel metal-oxide-semiconductor (MOS) FET, or MOSFET, is used.

The driving elements Q1 are connected in a parallel relationship with respect to the output line of the DC/DC converter 40, or in other words the supply line of the output voltage Vo, and the current control element Q2 is connected in parallel with the driving elements Q1.

Specifically, the source of each of the driving elements Q1 and the current control element Q2 is connected to the output line of the DC/DC converter 40. The drain of each driving element Q1 is connected to the anode of a corresponding light-emitting element 2a among the light-emitting elements 2a in the emission section 2.

As illustrated in the diagram, the cathode of each light-emitting element 2a is connected to ground (GND).

The drain of the current control element Q2 is connected to ground through the constant current source 30a, while the gate is connected to the node between the drain and the constant current source 30a.

The gate of each driving element Q1 is connected to the gate of the current control element Q2 through a corresponding switch SW.

In the driving circuit 30 having the above configuration, the driving elements Q1 whose switch SW is ON are electrically conductive, the driving voltage Vd based on the output voltage Vo is applied to the light-emitting elements 2a connected to the electrically conductive driving elements Q1, and the light-emitting elements 2a emit light.

At this time, a driving current Id flows to the light-emitting elements 2a, but in the driving circuit 30 having the above configuration, the driving elements Q1 and the current control element Q2 form a current mirror circuit, and the current value of the driving current Id is controlled by a value corresponding to the current value of the constant current source 30a.

By controlling the ON/OFF state of the switches SW in the driving circuit 30, the driving control section 31 controls the ON/OFF state of the light-emitting elements 2a. In the diagram, the control signal lines by which the driving control section 31 individually controls the ON/OFF state of each of the switches SW are labeled the control signal lines Ls.

The frame synchronization signal Fs is supplied to the driving control section 31 by the image sensor 7, thereby enabling the driving control section 31 to synchronize the ON timings and OFF timings of the light-emitting elements 2a with the frame cycle of the image sensor 7.

Additionally, the driving control section 31 is capable of controlling the ON/OFF state of the light-emitting elements 2a on the basis of an instruction from the control section 9.

Additionally, the driving control section 31 is also capable of controlling the ON/OFF state of the light-emitting elements 2a on the basis of the temperature of the emission section 2 detected by the temperature detection section 10.

Furthermore, the driving control section 31 is capable of instructing the DC/DC converter 40 in the power supply circuit 4 to adjust the output voltage Vo, but this control will be described in further detail later.

As illustrated in the diagram, in the driving section 3, a detection line Ld for detecting the voltage produced in each light-emitting element 2a is formed for each light-emitting element 2a. Specifically, in the configuration illustrated in FIG. 3, each detection line Ld is connected to the anode of the corresponding light-emitting element 2a.

The driving control section 31 in this example is provided with a configuration for individually detecting the voltage obtained on each detection line Ld, or in other words, the voltage of each light-emitting element 2a, but this configuration will be described in further detail later.

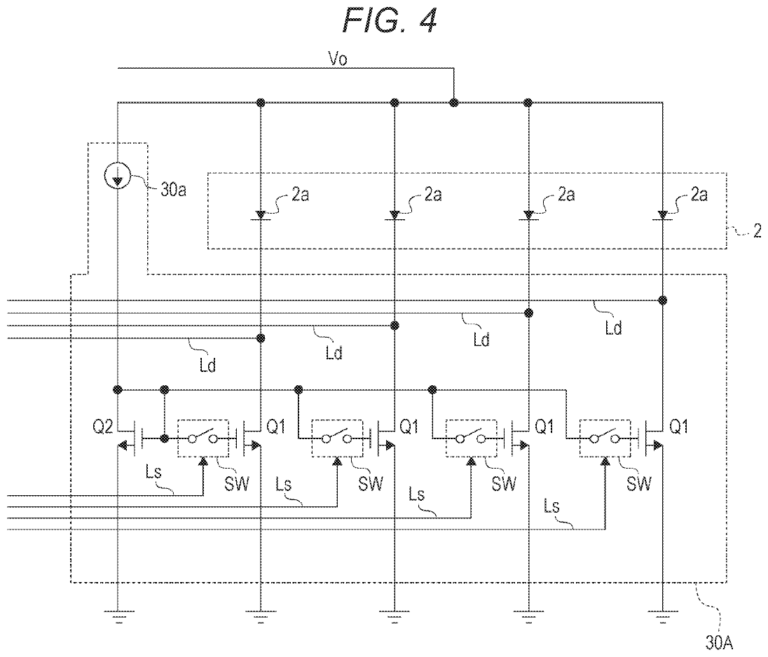

Here, FIG. 3 illustrates an example of a configuration in which a current mirror circuit containing the driving elements Q1 and the current control element Q2 is provided on the anode side of the light-emitting elements 2a, but like the driving circuit 30A illustrated in FIG. 4, a configuration in which the current mirror circuit is provided on the cathode side of the light-emitting elements 2a is also possible.

In this case, the anode of each light-emitting element 2a in the emission section 2 is connected to the output line of the DC/DC converter 40.

In this case, an N-channel MOSFET is used for each of the driving elements Q1 and the current control element Q2 forming the current mirror circuit. The drain and the gate of the current control element Q2 is connected to the output line of the DC/DC converter 40 through the constant current source 30a, while the source is connected to ground.

The drain of each driving element Q1 is connected to the cathode of the corresponding light-emitting element 2a, while the source is connected to ground. The gate of each driving element Q1 is connected to the gate and the drain of the current control element Q2 through each corresponding switch SW.

In this case as well, by controlling the ON/OFF state of the switches SW, the driving control section 31 can turn the light-emitting elements 2a ON/OFF.

Also, in this case, each detection line Ld is connected to the cathode of the corresponding light-emitting element 2a, in correspondence with the current mirror circuit being connected on the cathode side of the light-emitting elements 2a. In other words, the driving control section 31 in this case detects the voltage at the cathode of the light-emitting elements 2a.

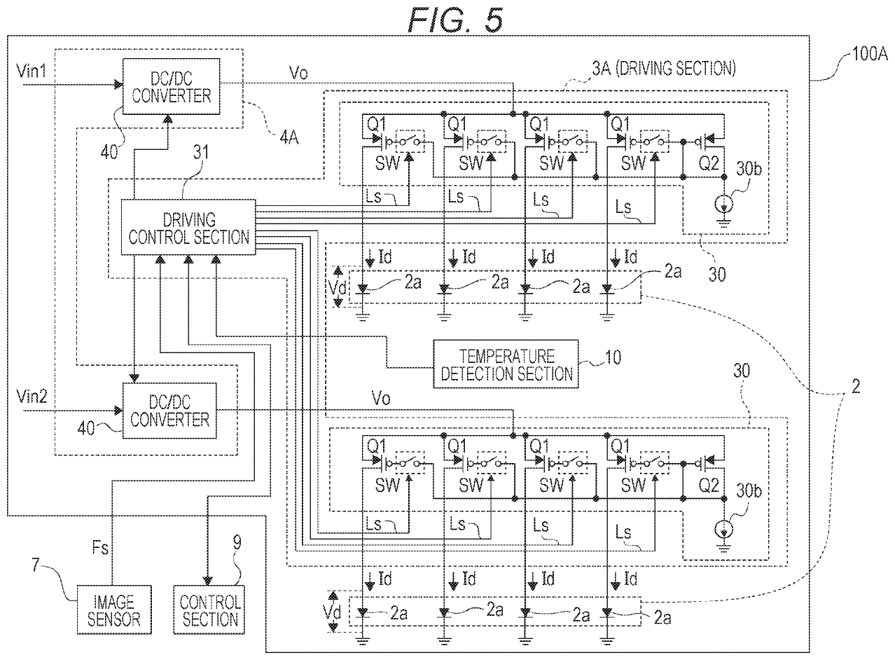

FIG. 5 illustrates an exemplary configuration of a light source apparatus 100A as a modification.

The light source apparatus 100A is different from the light source apparatus 100 on the point that a power supply circuit 4A is provided instead of the power supply circuit 4 and a driving section 3A is provided instead of the driving section 3.

The power supply circuit 4A includes multiple (in the illustrated example, two) DC/DC converters 40. An input voltage Vin1 is supplied to DC/DC converter 40, while an input voltage Vin2 is supplied to the other DC/DC converter 40. The driving section 3A is provided with multiple driving circuits 30 that accept the input of the output voltage Vo from the respectively different DC/DC converters 40. As illustrated in the diagram, in each driving circuit 30, a variable current source 30b is provided instead of the constant current source 30a. The variable current source 30b is a current source having a variable current value.

In this case, the light-emitting elements 2a in the emission section 2 are divided into multiple light-emitting element groups whose states are controlled ON/OFF by different driving circuits 30.

The driving control section 31 in this case controls the ON/OFF state of the switches SW in each driving circuit 30.

Note that the detection lines Ld are omitted from illustration in FIG. 5 for convenience, but in this case, because the current mirror circuit containing the driving elements Q1 and the current control element Q2 is connected on the anode side of the light-emitting elements 2a, each detection line Ld is connected to the anode of the corresponding light-emitting element 2a. In other words, the driving control section 31 in this case detects the voltage at the anode of the light-emitting elements 2a.

Like the light source apparatus 100A illustrated in FIG. 5, by taking a configuration in which at least the pair of the DC/DC converter 40 and the driving circuit 30 are reproduced as multiple subsystems, the driving current Id of the light-emitting elements 2a can be set to a different value for each subsystem. For example, by causing the voltage value of the output voltage Vo and the current value of the variable current source 30b to be different for each subsystem, the value of the driving current Id can be made different for each subsystem. Also, in a configuration in which the DC/DC converter 40 keeps the driving current Id constant, by making the target value of the constant current control different for each DC/DC converter 40, the value of the driving current Id can be made difference for each subsystem.

In the case of adopting a configuration like FIG. 5, it is conceivable to make the values of the output voltage Vo and the driving current Id different for each subsystem according to factors such as the emission intensity distribution and the temperature distribution in the emission section 2. For example, it is conceivable to take measures such as increasing the driving current Id and also raising the output voltage Vo for a subsystem corresponding to a high-temperature location in the emission section 2.

<4. Variations in Substrate Configuration>

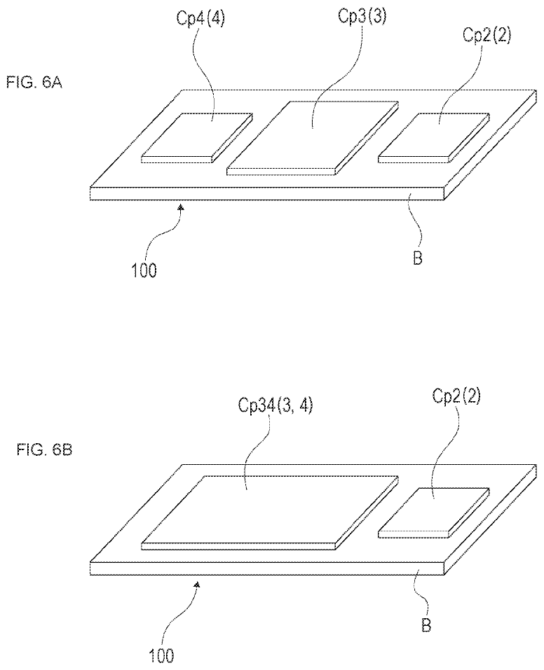

Here, the light source apparatus 100 may take the configurations illustrated in FIGS. 6 to 8.

As illustrated in FIG. 6A, the light source apparatus 100 may take a configuration in which a chip Cp2 containing a circuit that acts as the emission section 2, a chip Cp3 containing a circuit that acts as the driving section 3, and a chip Cp4 containing the power supply circuit 4 are formed on the same substrate B.

Additionally, the driving section 3 and the power supply circuit 4 may also be formed in the same chip Cp34, and in this case, the light source apparatus 100 may take a configuration in which the chip Cp2 and the chip Cp34 are formed on the same substrate B, as illustrated in FIG. 6B.

It is also possible to take a configuration in which a chip Cp is mounted on another chip Cp.

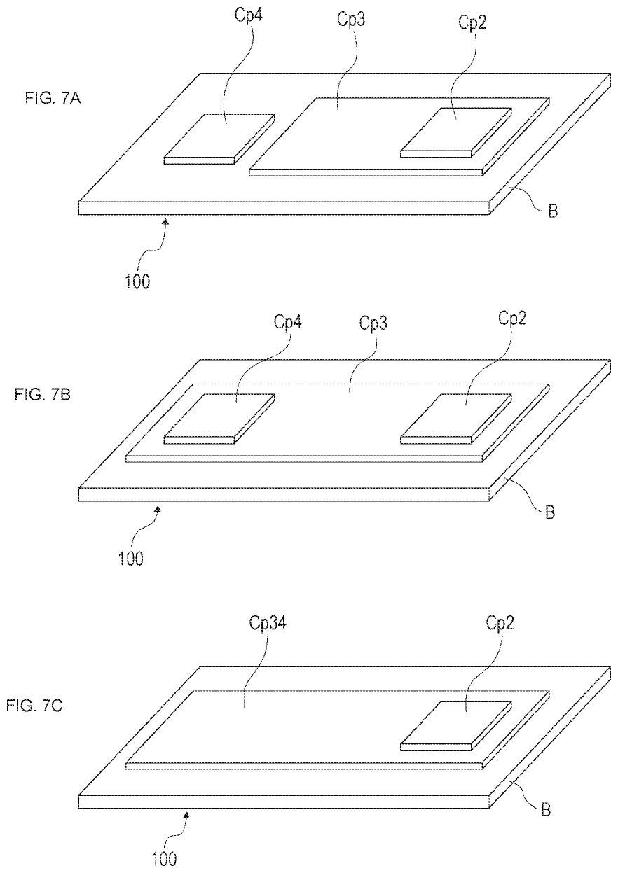

In this case, the light source apparatus 100 may take a configuration in which the chip Cp3 having the chip Cp2 mounted thereon and the chip Cp4 are formed on the substrate B like in FIG. 7A, a configuration in which the chip Cp3 having the chip Cp2 and the chip Cp4 mounted thereon is formed on the substrate B like in FIG. 7B, or a configuration in which the chip Cp34 having the chip Cp2 mounted thereon is formed on the substrate B like in FIG. 7C, for example.

Additionally, the light source apparatus 100 may also take a configuration that includes the image sensor 7.

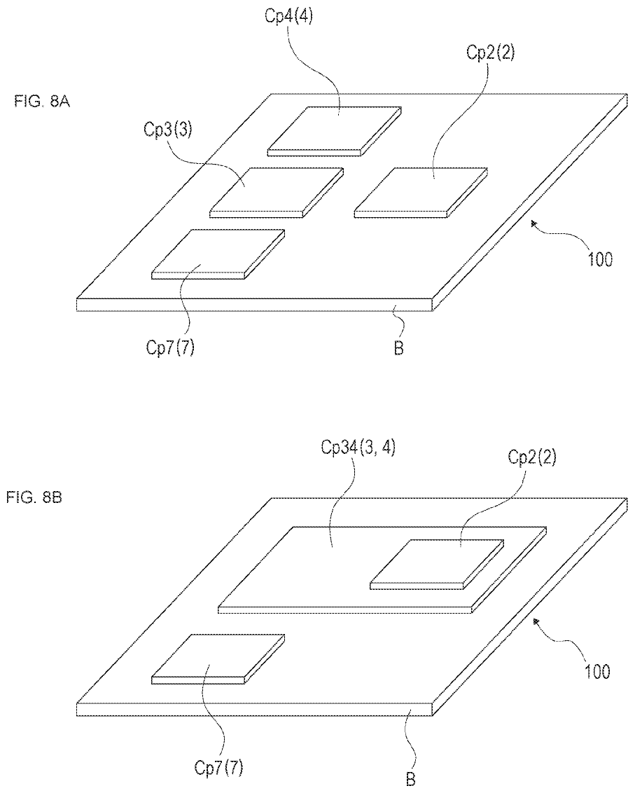

For example, FIG. 8A illustrates an example of a configuration of the light source apparatus 100 in which the chip Cp2, the chip Cp3, and the chip Cp4 as well as a chip Cp7 containing a circuit that acts as the image sensor 7 are formed on the same substrate B.

Also, FIG. 8B illustrates an example of a configuration of the light source apparatus 100 in which the chip Cp34 having the chip Cp2 mounted thereon and the chip Cp7 are formed on the same substrate B.

Note that the light source apparatus 100A described above likewise may adopt a configuration similar to those described using FIGS. 6 to 8.

Here, regarding the temperature detection section 10, in the case where the chip Cp2 is formed on the substrate B like in FIGS. 6A, 6B, and 8A for example, it is sufficient to form temperature detection elements such as diodes at positions near the chip Cp2 in the substrate B (such as positions beside the chip Cp2 on the substrate B, for example).

Also, in the case where the chip Cp2 is mounted onto another chip Cp like in FIGS. 7A to 7C and FIG. 8B, it is sufficient to form the temperature detection elements at positions near the chip Cp2 in the other chip Cp (such as positions underneath of the chip Cp2, for example).

The temperature detection section 10 may include a plurality of temperature sensors 10a including temperature detection elements such as diodes.

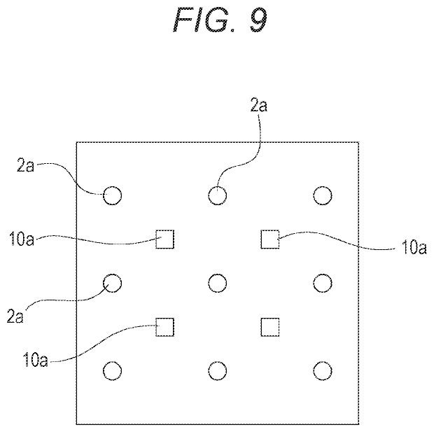

FIG. 9 illustrates an exemplary arrangement of the temperature sensors 10a in the case where the temperature detection section 10 includes a plurality of temperature sensors 10a.

In the example of FIG. 9, the plurality of temperature sensors 10a are not concentrated in a single location, but are dispersed in a plane parallel to the plane in which the light-emitting elements 2a are arrayed. Specifically, the plurality of temperature sensors 10a may be arranged such that one temperature sensor 10a is disposed for each emission block containing a predetermined number of light-emitting elements 2a, such as a 2×2 block containing a total of four light-emitting elements 2a, for example. In this case, the temperature sensors 10a may be arranged at equal intervals in a plane parallel to the plane in which the light-emitting elements 2a are arrayed.

Note that although FIG. 9 illustrates an example of arranging four temperature sensors 10a with respect to nine light-emitting elements 2a, but the number of disposed light-emitting elements 2a and the number of disposed temperature sensors 10a are not limited thereto.

Also, by dispersing the plurality of temperature sensors 10a like in the examples of FIG. 9, it is possible to detect an in-plane temperature distribution of the emission section 2. In addition, different temperatures can be detected for different areas of the emission surface, and furthermore, by increasing the number of disposed temperature sensors 10a, it is also possible to detect different temperatures for each of the light-emitting elements 2a.

<5. Exemplary VCSEL Structure>

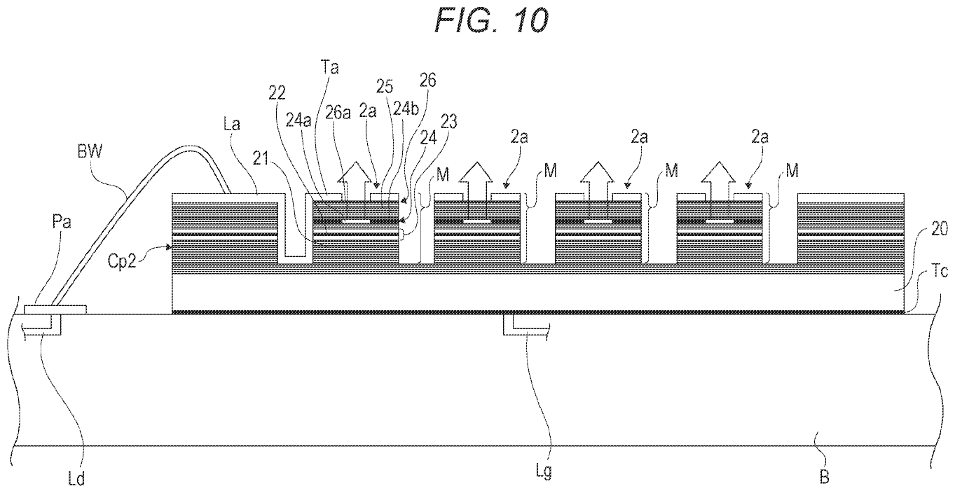

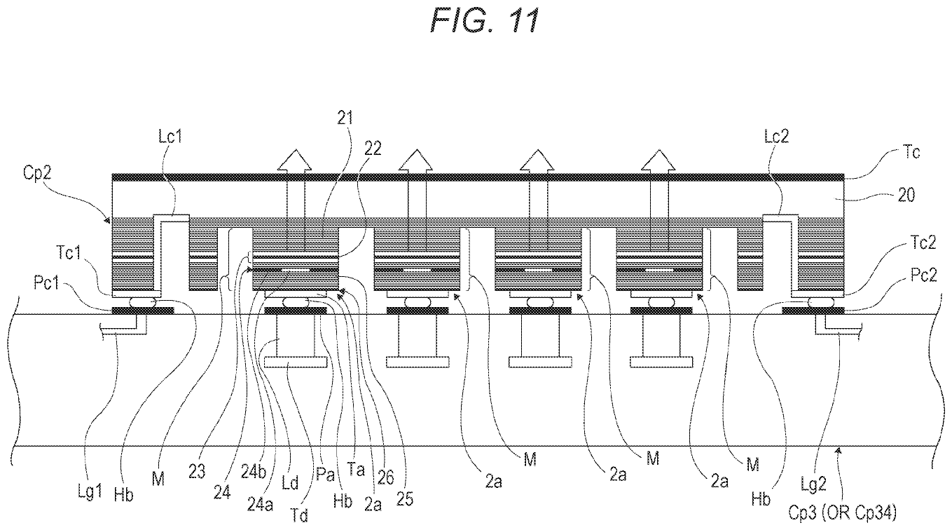

Next, an exemplary structure of the chip Cp2 in which the emission section 2 is formed will be described with reference to FIGS. 10 and 11.

FIG. 10 illustrates an exemplary structure of the chip Cp2 in the case of being formed on the substrate B like in FIGS. 6A, 6B, and 8A, while FIG. 11 illustrates an exemplary structure of the chip Cp2 in the case of being mounted onto another chip Cp like in FIGS. 7A to 7C and FIG. 8B.

Note that, as an example, FIGS. 10 and 11 illustrate an exemplary structure corresponding to the case where the driving circuit 30 (current mirror circuit) is inserted on the anode side of the light-emitting elements 2a (see FIG. 3).

As illustrated in FIG. 10, in the chip Cp2, the portions corresponding to each of the light-emitting elements 2a are formed as mesas M.

A semiconductor substrate 20 is used as the substrate of the chip Cp2, and a cathode electrode Tc is formed on the underside of the semiconductor substrate 20. For the semiconductor substrate 20, a gallium arsenide (GaAs) substrate is used, for example.

On the semiconductor substrate 20, in each mesa M, a first multilayer reflective layer 21, an active layer 22, a second multilayer reflective layer 25, a contact layer 26, and an anode electrode Ta are formed in order from bottom to top.

A current constriction layer 24 is formed in a part (specifically the lower part) of the second multilayer reflective layer 25. Also, the portion including the active layer 22 that is sandwiched between the first multilayer reflective layer 21 and the second multilayer reflective layer 25 acts as a resonator 23.

The first multilayer reflective layer 21 is formed using a compound semiconductor exhibiting N-type conductivity, while the second multilayer reflective layer 25 is formed using a compound semiconductor exhibiting P-type conductivity.

The active layer 22 acts as a layer for generating laser light, while the current constriction layer 24 acts as a layer that injects current efficiently into the active layer 22 and achieves a lens effect.

After the mesas M are formed, the current constriction layer 24 is subjected to selective oxidation in the unoxidized state, and includes a central oxidized region (also referred to as a selectively oxidized region) 24a and an unoxidized region 24b that is not oxidized in the periphery of the oxidized region 24a. In the current constriction layer 24, a current constricting structure is formed by the oxidized region 24a and the unoxidized region 24b, and current is conducted to the current constriction region as the unoxidized region 24b.

The contact layer 26 is provided to ensure an ohmic contact with the anode electrode Ta.

The anode electrode Ta is formed on the contact layer 26 in an annular (ring) shape or the like that is open in the center for example when looking at a plan view of the substrate B. In the contact layer 26, the portion where the anode electrode Ta is not formed on top acts as an opening 26a.

Light generated in the active layer 22 travels back and forth inside the resonator 23 and then is emitted to the outside through the opening 26a.

Here, the cathode electrode Tc in the chip Cp2 is connected to ground through a ground lead Lg formed in a wiring layer of the substrate B.

Also, in the diagram, a pad Pa represents a pad for the anode electrode formed on the substrate B. The pad Pa is connected to the drain of any one of the driving elements Q1 included in the driving circuit 30 through a lead Ld formed in the wiring layer of the substrate B.

In the diagram, the anode electrode Ta is illustrated as being connected to the single pad Pa through an anode lead La formed on the chip Cp2 and a bonding wire BW for only one light-emitting element 2a, but the pad Pa and the lead Ld are formed for each light-emitting element 2a on the substrate B, and furthermore, the anode lead La is formed for each of the light-emitting elements 2a on the chip Cp2, and the anode electrodes Ta of the individual light-emitting elements 2a are connected to the corresponding pad Pa through the corresponding anode lead La and bonding wire BW.

Next, in the case of FIG. 11, a back-illumination chip Cp2 is used as the chip Cp2. In other words, rather than emitting light in the upward direction (surface direction) of the semiconductor substrate 20 like the example in FIG. 10, a chip Cp2 of a type that emits light in the back direction of the semiconductor substrate 20.

In this case, an opening for emitting light is not formed in the anode electrode Ta, and the opening 26a is not formed in the contact layer 26.

In the chip Cp3 (or the chip Cp34; the same applies hereinafter in the description of FIG. 11) in which the driving section 3 (driving circuit 30) is formed, the pad Pa for establishing an electrical connection with the anode electrode Ta is formed for each light-emitting element 2a. In the wiring layer of the chip Cp3, the lead Ld is formed for each pad Pa. Although omitted from illustration, each of the pads Pa is connected, by these leads Ld, to the drain of a corresponding driving element Q1 in the driving circuit 30 formed in the chip Cp3.

Also, in the chip Cp2, the cathode electrode Tc is connected to an electrode Tc1 and an electrode Tc2 via leads Lc1 and Lc2, respectively. The electrode Tc1 and the electrode Tc2 are electrodes for respectively connecting with a pad Pc1 and a pad Pc2 formed in the chip Cp3.

In the wiring layer of the chip Cp3, a ground lead Lg1 connected to the pad Pc1 and a ground lead Lg2 connected to the pad Pc2 are formed. Although not illustrated, these ground leads Lg1 and Lg2 are connected to ground.

The connections between each anode electrode Ta in the chip Cp2 and each pad Pa in the chip Cp3 as well as the connections between the electrodes Tc1 and Tc2 in the chip Cp2 and the pads Pc1 and Pc2 in the chip Cp3 are established through respective solder bumps Hb.

In other words, the mounting of the chip Cp2 on the chip Cp3 in this case is achieved by what is called flip chip mounting.

<6. Voltage Detection and Control as an Embodiment>

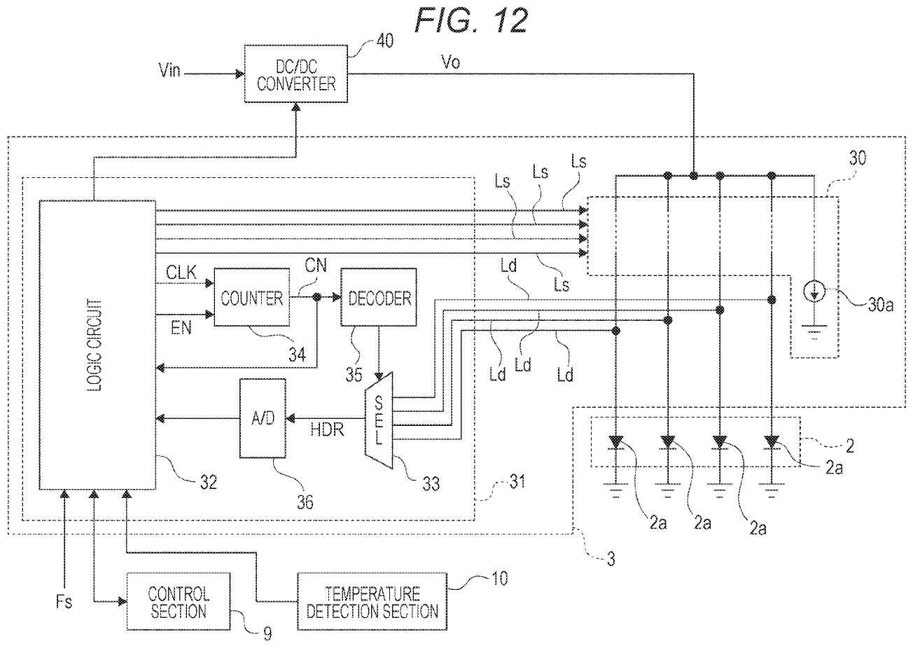

FIG. 12 is an explanatory diagram of an exemplary configuration for achieving voltage detection as an embodiment, and illustrates an exemplary internal configuration of the driving section 3 in the light source apparatus 100 (particularly an exemplary internal configuration of the driving control section 31) together with the emission section 2, the DC/DC converter 40, the control section 9, and the temperature detection section 10.

In this example, the driving control section 31 individually detects the voltages of the plurality of light-emitting elements 2a in the emission section 2 by time division. As a configuration for this purpose, the driving control section 31 includes a selector 33, a counter 34, a decoder 35, and an A/D converter 36.

Additionally, the driving control section 31 includes a logic circuit 32 that controls the ON/OFF state of each switch SW in the driving circuit 30.

Here, the logic circuit 32 is connected to the control section 9 and is capable of controlling the ON/OFF state of the light-emitting elements 2a on the basis of an instruction from the control section 9. At this time, the logic circuit 32 synchronizes the ON timing and the OFF timing of each light-emitting element 2a with the frame cycle of the image sensor 7, on the basis of the frame synchronization signal Fs supplied from the image sensor 7. Additionally, the logic circuit 32 is also capable of controlling the ON/OFF state of the light-emitting elements 2a on the basis of the temperature of the emission section 2 detected by the temperature detection section 10.

The selector 33 has a number of input terminals at least equal to the number of detection lines Ld, and each input terminal is connected to the anode of a corresponding light-emitting element 2a through the corresponding detection line Ld. In this example, the configuration of the selector 33 may be provided with a switch circuit such as a transfer gate circuit for each detection line Ld, for example.

A clock CLK is input into the counter 34 from the logic circuit 32. The status of the counter 34 is enabled by an enable signal EN input by the logic circuit 32, thereby causing the counter 34 to start a counting operation based on the clock CLK and also to start outputting a count value CN obtained by the counting operation. As illustrated in the diagram, the count value CN is supplied to each of the decoder 35 and the logic circuit 32.

The decoder 35 instructs the selector 33 to select one of the detection lines Ld according to the count value CN.

The selector 33 outputs the voltage value obtained from the single detection line Ld indicated by the decoder 35 from among the detection lines Ld to the A/D converter 36 as an output value HDR.

The A/D converter 36 digitally samples the input voltage value (an analog value), and outputs the sampled voltage value (a digital value) to the logic circuit 32.

Here, the logic circuit 32 makes a determination (voltage abnormality determination) regarding whether the voltage of each light-emitting element 2a is abnormal on the basis of the voltage value of the light-emitting elements 2a detected according to time division by the selector 33, the counter 34, the decoder 35, and the A/D converter 36 described above.

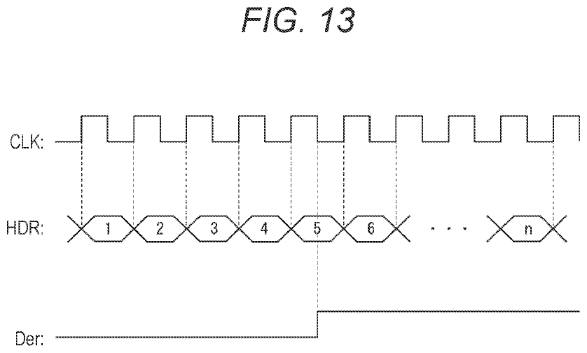

FIG. 13 is a diagram illustrating an example of the relationship between the clock CLK used in the time-division detection, the output value HDR (digital value) input into the logic circuit 32, and an abnormality detection signal Der generated internally by the logic circuit 32. Note that the diagram illustrates an example of a case in which the number of light-emitting elements 2a is n, and n is seven or more.

In the diagram, the numbers attached to the output value HDR represent different light-emitting elements 2a whose voltage values are input into the logic circuit 32 (in other words, different detection lines Ld selected by the selector 33).

The error detection signal Der is generated as a signal that is raised (or lowered) in response to determining the presence of an abnormality in the output value HDR as the successively different output values HDR of the light-emitting elements 2a are input in this way. The diagram illustrates an example in which the output value HDR of the fifth light-emitting element 2a (the light-emitting element 2a whose voltage value is input fifth into the logic circuit logic circuit 32) is determined to be abnormal, and in response, the error detection signal Der is raised at the fifth timing.

In this example, the determination of the presence or absence of a voltage abnormality in the light-emitting elements 2a is made by determining whether or not the output value HDR is a value inside a predetermined range prescribed by an upper threshold THu and a lower threshold THd (where THu>THd).

With this arrangement, the presence or absence of a voltage abnormality in a light-emitting element 2a caused by a discontinuity, a short, a ground fault, or the like can be specified appropriately.

In the case where a voltage abnormality in a light-emitting element 2a is recognized by the above determination, the logic circuit 32 writes an error flag in a register. By writing the error flag to the register in this way, the control section 9 or the like can be notified that an abnormality has occurred in the emission section 2, for example.

Here, in this example, the count value CN from the counter 34 is input into the logic circuit 32, and the logic circuit 32 is capable of specifying the light-emitting element 2a being treated as the detection target on the basis of the input count value CN. Particularly, in the case of making an abnormality determination like the above, it is possible not only to determine the presence or absence of an abnormality, but also to specify the light-emitting element 2a where the abnormality has occurred.

Also, the logic circuit 32 in this example controls the output voltage Vo on the basis of the output value HDR.

Specifically, the logic circuit 32 determines whether or not the output value HDR input by the A/D converter 36 is a threshold THe or higher (where THd<THe<THu), and in the case where the output value HDR is the threshold THe or higher, the logic circuit 32 outputs a power supply control signal for raising the output voltage Vo to the DC/DC converter 40.

Here, in this example, the light-emitting elements 2a are driven on the basis of a common power supply voltage (the output voltage Vo) generated by a common power supply circuit (the DC/DC converter 40). By taking such a configuration, a reduction in the circuit scale may be attained compared to the case of adopting a configuration capable of adjusting the power supply voltage for each light-emitting element 2a.

At this time, because the light-emitting elements 2a have individual inconsistencies in properties such as the forward voltage (VF), in the case of a configuration that drives the plurality of light-emitting elements 2a on the basis of a common power supply voltage like the present example, it is important to adjust the magnitude of the power supply voltage to suit the voltage of a light-emitting element having a high detected voltage, so that all of the light-emitting elements 2a targeted for emission are made to emit light appropriately.

Consequently, the power supply is controlled as above to adjust the magnitude of the common power supply voltage to suit the voltage of a light-emitting element 2a having a high detected voltage.

With this arrangement, all of the light-emitting elements 2a targeted for emission can be made to emit light appropriately while also attaining a reduction in the circuit scale through the adoption of a configuration that drives the plurality of light-emitting elements 2a on the basis of a common power supply voltage.

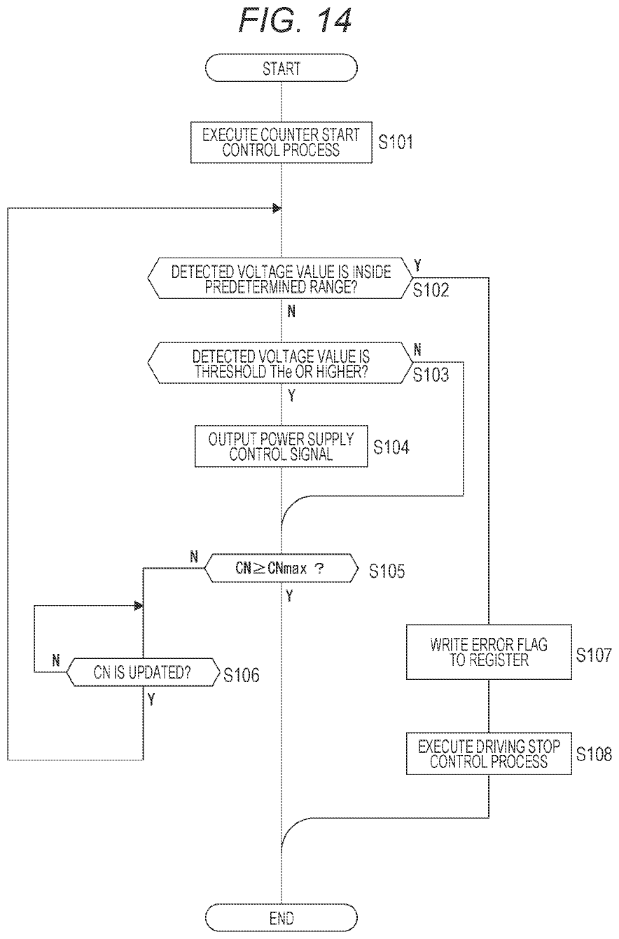

FIG. 14 is a flowchart illustrating a specific processing procedure to be executed by the logic circuit 32 to achieve the abnormality determination and the power supply control described above.

First, as a counter start control process in step S101, the logic circuit 32 performs a process of setting the counter 34 to the enabled state with the enable signal EN. With this arrangement, the counter 34 starts, and voltage detection by time division is initiated. Note that the timing of initiating such voltage detection by time division may be immediately before starting distance measurement, at power-on, at fixed intervals, or the like, for example. Also, in the case where the distance measuring apparatus 1 is an information processing terminal such as a smartphone or a tablet for example, it is also conceivable to start voltage detection in response to resuming from a sleep state.

In step S102 that follows step S101, the logic circuit 32 determines whether or not the detected voltage value is inside a predetermined range, or in other words, whether or not the output value HDR input by the A/D converter 36 is the lower threshold THd or higher and also the upper threshold THu or lower.

In step S102, in the case where the output value HDR is the lower threshold THd or higher and also the upper threshold THu or lower, and the detected voltage value is determined to be inside the predetermined range, the logic circuit 32 proceeds to step S103 and determines whether or not the detected voltage value is the threshold THe or higher. In the case where the detected voltage value is the threshold THe or higher, in step S104, the logic circuit 32 executes a process of outputting a power supply control signal, or in other words a process of outputting a power supply control signal instructing the DC/DC converter 40 to raise the output voltage Vo, and then in step S105, the logic circuit 32 executes a process of checking the count value CN.

On the other hand, if the detected voltage value is not the threshold THe or higher, the logic circuit 32 skips the output process in step S104 and executes the process of checking the count value CN in step S105.

As the process of checking the count value CN in step S105, the logic circuit 32 determines whether or not the count value CN is a maximum value CNmax or greater. The maximum value CNmax is set to a value equal to the number of light-emitting elements 2a treated as the targets of voltage detection.

In step S105, if the count value CN is not the maximum value CNmax or greater, in step S106, the logic circuit 32 stands by until the count value CN is updated, and returns to the determination process in step S102. With this arrangement, the presence or absence or a voltage abnormality is determined for the next light-emitting element 2a.

Also, in step S105, if the count value CN is the maximum value CNmax or greater, the logic circuit 32 ends the series of processes illustrated in the flowchart.

In step S102, if the detected voltage value is not inside the predetermined range (not the lower threshold THd or higher, or not the upper threshold THu or lower), the logic circuit 32 proceeds to step S107 and writes an error flag to a register, executes a driving stop control process in step S108, and ends the series of processes illustrated in the flowchart. The driving stop control process in step S108 is a control process for stopping the emission driving of the light-emitting elements 2a, such as by stopping the DC/DC converter 40, for example.

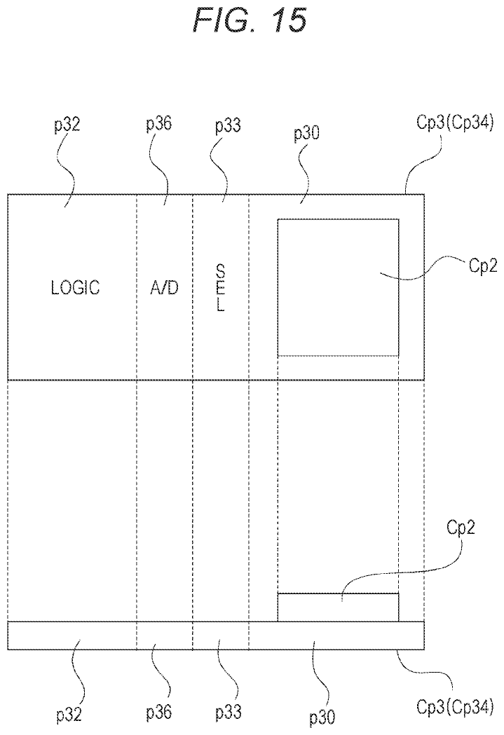

FIG. 15 is a diagram illustrating an example of the layout, on a chip, of the components forming the driving section 3.

As described earlier, the driving section 3 can be mounted as a chip Cp3 (or a chip Cp34; the same applies to the description of FIG. 15 below), and furthermore, a chip Cp2 can be mounted as the emission section 2 onto the chip Cp3 in a flip chip configuration (for example, see FIG. 11).

The driving circuit 30 (the driving elements Q1 and the current control element Q2) in the driving section 3 may be disposed at a position directly underneath the chip Cp2 in the chip Cp3, as illustrated by the region p30 in the diagram. Also, the selector 33 in the driving control section 31 may be disposed in a region p33 adjacent to the region p30 in the chip Cp3, while the A/D converter 36 may be disposed in a region p36 adjacent to the region p33 on the opposite side from the region p30. In addition, components such as the logic circuit 32, the counter 34, and the decoder 35 may be disposed in a region p32 adjacent to the region p36 on the opposite side from the region p33.

According to such an arrangement for example, the logic circuit 32 that acts as a source of heat is separated from the emission section 2 and the driving circuit 30 that also act as a source of heat, and a suppression of a rise in the temperature may be attained.

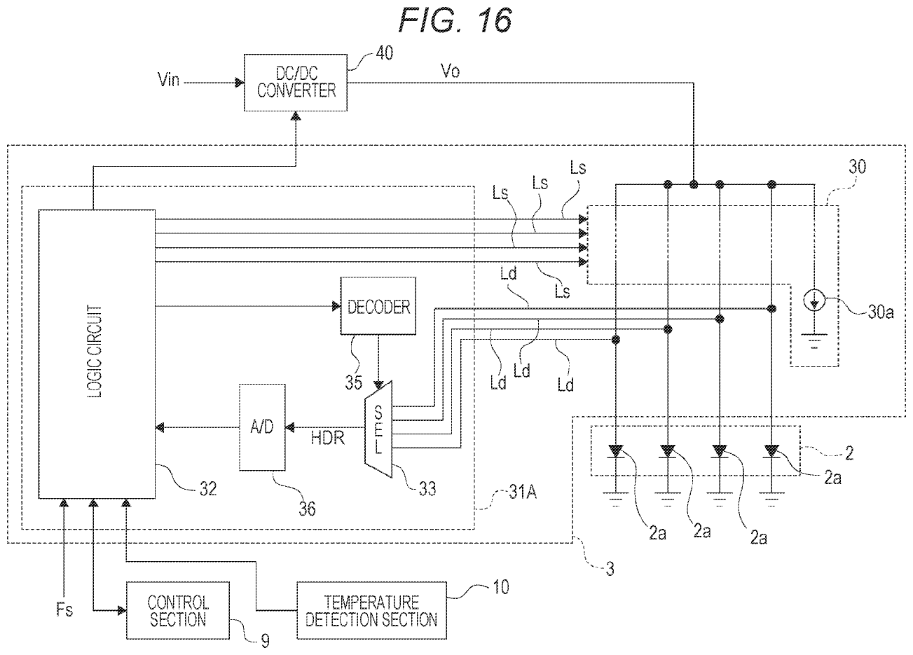

Herein, the foregoing describes an example of a configuration that uses the counter 34 as an exemplary configuration for performing time-division detection, but a configuration that omits the counter 34 like the driving control section 31A illustrated in FIG. 16 may also be adopted.

In this case, the logic circuit 32 is no longer capable of specifying the correspondence relationship between the detected voltage values and the light-emitting elements 2a on the basis of the count value CN. However, in the case where the logic circuit 32 controls the switches SW to drive the plurality of light-emitting elements 2a in a scanning manner, for example, the logic circuit 32 is capable of understanding which light-emitting element 2a is being made to emit light, and therefore by controlling the decoder 35 to cause the selector 33 to select the detection line Ld connected to the light-emitting element 2a that is emitting light, it is possible to specify the correspondence relationship between the detected voltage values and the light-emitting elements 2a.

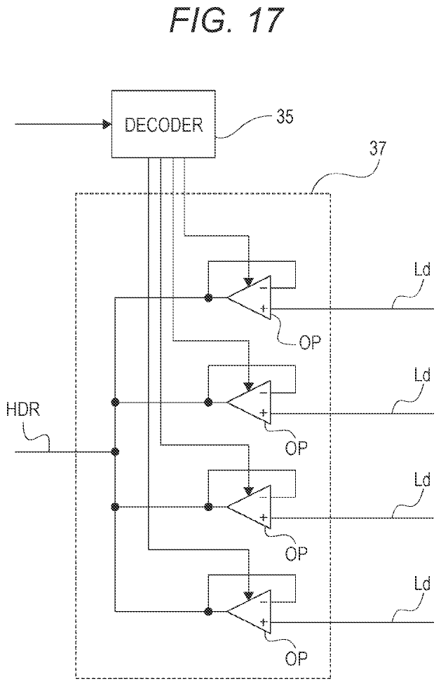

Also, the foregoing gives an example of using a selector that uses a transfer gate as the selector 33, but a configuration using a voltage follower with an enable function like the selector circuit 37 illustrated in the example of FIG. 17 may also be adopted.

As illustrated in the diagram, in the selector circuit 37, an op-amp OP is provided for each detection line Ld, the non-inverting terminal of each op-amp OP is connected to the corresponding detection line Ld while the inverting terminal is connected to the output terminal, thereby causing the op-amp OP to function as a voltage follower. As illustrated in the diagram, in each op-amp OP, the node between the output terminal and the inverting terminal is connected to the line of the output value HDR.

In this case, by controlling the ON/OFF state of each op-amp OP according to the count value CN of the counter 34 or an instruction from the logic circuit 32, the decoder 35 successively switches the op-amp OP set to the ON state (enabled). With this arrangement, the output value HDR from the selector circuit 37 is successively switched to express the voltage values of the plurality of light-emitting elements 2a.

By using the selector circuit 37 like the above, it is possible to provide not only the function of the selector 33 (that is, the function of selecting the detection lines Ld by time division) but also a function of preventing a voltage drop on the detection lines Ld.

Note that, although omitted from the description referencing the diagrams, even in the case of a configuration that detects the voltage at the cathode of the light-emitting elements 2a as illustrated in FIG. 4, a similar configuration can be adopted for the voltage detection and voltage abnormality determination by time division described above as well as the power supply control based on the detected voltage.

<7. Summary of Embodiment and Modifications>

As described above, the light source apparatus (the distance measuring apparatus 1) as an embodiment includes an emission section (2) in which a plurality of vertical-cavity surface-emitting laser light-emitting elements (2a) is arrayed, and a detection section (the selector 33 or the selector circuit 37, the decoder 35, and the A/D converter 36) configured to detect a voltage at an anode or a cathode of the plurality of light-emitting elements in the emission section individually by time division.

With this arrangement, it is not necessary to provide a circuit for detecting voltage with respect to each light-emitting element.

Therefore, a reduction in the circuit scale may be attained for the purpose of detecting voltage, and a more compact apparatus may be attained while also enabling the voltage to be detected for each light-emitting element in a light source apparatus provided with an emission section in which a plurality of vertical-cavity surface-emitting laser light-emitting elements is arrayed.

In addition, in the light source apparatus as an embodiment, the detection section switches the light-emitting element to detect according to a clock, and includes a counter (34) configured to count in synchronization with the clock.

From the count value of the counter, it is possible to specify the light-emitting element from which the detected voltage value has been detected.

Consequently, when a voltage abnormality occurs, the light-emitting element where the abnormality has occurred can be specified.

Further, in the light source apparatus as an embodiment, the detection section includes a detection line of the voltage (Ld) from each light-emitting element, and a voltage follower (the op-amp OP) inserted onto each detection line and having a controllable ON/OFF state.

With this arrangement, not only a detection line time-division selection function but also a detection line voltage drop prevention function can be provided together.

Further, it is desirable that the light source apparatus as an embodiment described above include a driving circuit (30 or 30A) configured to send a driving current to the plurality of light-emitting elements through a current mirror circuit.

With this arrangement, it is not necessary to use a power supply circuit with a constant current control function to send a constant current to the light-emitting elements.

Consequently, a simplification of the circuit configuration may be attained.

Further, in the light source apparatus as an embodiment, the current mirror circuit is connected to an anode side of the light-emitting elements, and the detection section is configured to detect the voltage at the anode of the light-emitting elements (see FIG. 12 and the like).

With this arrangement, voltage detection can be done appropriately with consideration for specific individual differences among each of the light-emitting elements and the driving elements in the current mirror circuit.

Further, in the light source apparatus as an embodiment, the current mirror circuit is connected to a cathode side of the light-emitting elements, and the detection section is configured to detect the voltage at the cathode of the light-emitting elements.

With this arrangement, voltage detection can be done appropriately with consideration for specific individual differences among each of the light-emitting elements and the driving elements in the current mirror circuit.

Furthermore, the light source apparatus as an embodiment includes a determination section (logic circuit 32) configured to determine a presence of an abnormality in the light-emitting elements on the basis of the voltage individually detected by the detection section.

With this arrangement, it is not necessary to provide a circuit for detecting a voltage abnormality with respect to each light-emitting element.

Consequently, a reduction in the circuit scale of the light source apparatus may be attained.

Further, in the light source apparatus as an embodiment, the determination section is configured to determine whether or not a value of the voltage is inside a predetermined range as the determination of the presence or absence of an abnormality in the light-emitting elements.

With this arrangement, the presence or absence of a voltage abnormality in a light-emitting element caused by a discontinuity, a short, a ground fault, or the like can be specified appropriately.

The light source apparatus as an embodiment further includes a power supply circuit (4) configured to generate a power supply voltage used in common to the drive the plurality of light-emitting elements, and a control section (the logic circuit 32) configured to control the power supply circuit on the basis of the voltage detected by the detection section.

With this arrangement, in a configuration in which a plurality of light-emitting elements is driven on the basis of a common power supply voltage generated by a common power supply circuit, it is possible to control the power supply such that, for example, if a voltage abnormality in a light-emitting element is recognized, the operation of the power supply circuit may be stopped or the like to increase safety, or the magnitude of the power supply voltage may be adjusted to suit a light-emitting element having a high detected voltage and thereby cause all light-emitting elements targeted for emission to emit light appropriately.

Consequently, in a configuration in which a plurality of light-emitting elements are driven on the basis of a common power supply voltage generated by a common power supply circuit, appropriate power supply control based on the voltage detected individually for each light-emitting element can be executed.

Furthermore, in the light source apparatus as an embodiment, the control section is configured to control the power supply circuit to raise the power supply voltage in response to the detection section detecting the voltage at a predetermined threshold (the threshold THe) or higher.

With this arrangement, in a configuration in which a plurality of light-emitting elements is driven on the basis of a common power supply voltage generated by a common power supply circuit, it is possible to adjust the magnitude of the common power supply voltage to suit a light-emitting element having a high detected voltage.

Consequently, all of the light-emitting elements targeted for emission can be made to emit light appropriately, without adopting a configuration capable of adjusting the power supply voltage for each light-emitting element. In other words, all of the light-emitting elements sharing a common power supply voltage can be made to emit light appropriately while also preventing the increase in circuit scale that occurs with a configuration capable of adjusting the power supply voltage for each light-emitting element.

Further, the light source apparatus as an embodiment includes a driving circuit (30 or 30A) having a switch (SW) provided for each light-emitting element and configured to drive the light-emitting elements in the emission section individually.

With this arrangement, the emission section can be made to emit light according to any emission pattern (two-dimensional light/dark pattern).

Consequently, in the case where variable emission patterns are demanded in relation to light emission for distance measurement, it is not necessary to provide a plurality of emission sections having fixed emission patterns, and a reduction in the number of components and a miniaturization of the light source apparatus may be attained.

Also, in the case of an individually drivable configuration, because the driving control section of the light-emitting elements is capable of knowing which light-emitting element is being driven (emitting light), if the detected voltage value is a fixed value or higher when detecting the voltage of a light-emitting element that is not being made to emit light, it is possible to determine that a short exists with the wiring of another light-emitting element that is emitting light.

Further, a detection method as an embodiment is a detection method to detect individually by time division, a voltage at an anode or a cathode of a plurality of light-emitting elements in an emission section in which a plurality of vertical-cavity surface-emitting laser light-emitting elements is arrayed.

Furthermore, a sensing module as an embodiment includes the light source apparatus as an embodiment, and an image sensor (7) that captures an image by receiving light that is emitted by the emission section (2) provided in the light source apparatus and then reflected by a subject (for example, see a configuration illustrated in FIG. 8).

Action and effects similar to the light source apparatus according to the embodiment described above may also be obtained with a driving method and a sensing module according to such an embodiment.

Note that the above describes an example of a configuration in which the switch SW is provided for each light-emitting element 2a to enable individual control of each light-emitting element 2a, but in the present technology, a configuration enabling the individual driving of each light-emitting element 2a is not essential.

Additionally, although the above describes an example in which the present technology is applied to a distance measuring apparatus, the present technology is not limited to being applied to a light source for distance measurement.

Note that the effects described in this specification are merely non-limiting examples, and there may be other effects.

<8. Present Technology>

Note that the present technology may be configured as below.

(1)

A light source apparatus including:

an emission section in which a plurality of vertical-cavity surface-emitting laser light-emitting elements is arrayed; and

a detection section configured to detect a voltage at an anode or a cathode of the plurality of light-emitting elements in the emission section individually by time division.

(2)

The light source apparatus according to (1), in which

the detection section

switches the light-emitting element to detect according to a clock, and

includes a counter configured to count in synchronization with the clock.

(3)

The light source apparatus according to (1) or (2), in which

the detection section includes

a detection line of the voltage from each light-emitting element, and

a voltage follower inserted onto each detection line and having a controllable ON/OFF state.

(4)

The light source apparatus according to any one of (1) to (3), further including:

a driving circuit configured to send a driving current to the plurality of light-emitting elements through a current mirror circuit.

(5)

The light source apparatus according to (4), in which

the current mirror circuit is connected to an anode side of the light-emitting elements, and

the detection section

is configured to detect the voltage at the anode of the light-emitting elements.

(6)

The light source apparatus according to (4), in which

the current mirror circuit is connected to a cathode side of the light-emitting elements, and

the detection section

is configured to detect the voltage at the cathode of the light-emitting elements.

(7)

The light source apparatus according to any one of (1) to (6), further including:

a determination section configured to determine a presence of an abnormality in the light-emitting elements on the basis of the voltage individually detected by the detection section.

(8)

The light source apparatus according to (7), in which

the determination section

is configured to determine whether or not a value of the voltage is inside a predetermined range as the determination of the presence or absence of an abnormality in the light-emitting elements.

(9)

The light source apparatus according to any one of (1) to (8), further including:

a power supply circuit configured to generate a power supply voltage used in common to the drive the plurality of light-emitting elements; and

a control section configured to control the power supply circuit on the basis of the voltage detected by the detection section.

(10)

The light source apparatus according to (9), in which

the control section

is configured to control the power supply circuit to raise the power supply voltage in response to the detection section detecting the voltage at a predetermined threshold or higher.

(11)

The light source apparatus according to any one of (1) to (10), further including:

a driving circuit having a switch provided for each light-emitting element and configured to drive the light-emitting elements in the emission section individually.

### REFERENCE SIGNS LIST

1 Distance measuring apparatus
2 Emission section
2a Light-emitting element
3, 3A Driving section
7 Image sensor
10 Temperature detection section
S Subject
B Substrate
Cp2, Cp3, Cp4, Cp34, Cp7 Chip
30, 30A Driving circuit
31, 31A Driving control section
Q1 Driving element
Q2 Current control element
SW Switch
32 Logic circuit
33 Selector
34 Counter
35 Decoder
36 A/D converter
37 Selector circuit
100, 100A Light source apparatus

1. A light source apparatus comprising:
an emission section in which a plurality of vertical-cavity surface-emitting laser light-emitting elements is arrayed; and
a detection section configured to detect a voltage at an anode or a cathode of the plurality of light-emitting elements in the emission section individually by time division.

2. The light source apparatus according to claim 1, wherein
the detection section
switches the light-emitting element to detect according to a clock, and
includes a counter configured to count in synchronization with the clock.

3. The light source apparatus according to claim 1, wherein
the detection section includes
a detection line of the voltage from each light-emitting element, and
a voltage follower inserted onto each detection line and having a controllable ON/OFF state.

4. The light source apparatus according to claim 1, further comprising:
a driving circuit configured to send a driving current to the plurality of light-emitting elements through a current mirror circuit.

5. The light source apparatus according to claim 4, wherein
the current mirror circuit is connected to an anode side of the light-emitting elements, and
the detection section
is configured to detect the voltage at the anode of the light-emitting elements.

6. The light source apparatus according to claim 4, wherein
the current mirror circuit is connected to a cathode side of the light-emitting elements, and
the detection section
is configured to detect the voltage at the cathode of the light-emitting elements.

7. The light source apparatus according to claim 1, further comprising:
a determination section configured to determine a presence of an abnormality in the light-emitting elements on a basis of the voltage individually detected by the detection section.

8. The light source apparatus according to claim 7, wherein
the determination section
is configured to determine whether or not a value of the voltage is inside a predetermined range as the determination of the presence or absence of an abnormality in the light-emitting elements.

9. The light source apparatus according to claim 1, further comprising:
a power supply circuit configured to generate a power supply voltage used in common to the drive the plurality of light-emitting elements; and
a control section configured to control the power supply circuit on a basis of the voltage detected by the detection section.

10. The light source apparatus according to claim 9, wherein
the control section
is configured to control the power supply circuit to raise the power supply voltage in response to the detection section detecting the voltage at a predetermined threshold or higher.

11. The light source apparatus according to claim 1, further comprising:
a driving circuit having a switch provided for each light-emitting element and configured to drive the light-emitting elements in the emission section individually.

12. A detection method comprising:
individually detecting, by time division, a voltage at an anode or a cathode of a plurality of light-emitting elements in an emission section in which a plurality of vertical-cavity surface-emitting laser light-emitting elements is arrayed.

13. A sensing module comprising:
a light source apparatus including an emission section in which a plurality of vertical-cavity surface-emitting laser light-emitting elements is arrayed, and a detection section configured to detect a voltage at an anode or a cathode of a plurality of light-emitting elements in the emission section individually by time division; and
an image sensor configured to capture an image by receiving light emitted by the emission section and reflected by a subject.
